(19) United States
(12) Patent Application Publication
(10) Pub. No.: US 2024/0339556 A1
(43) Pub. Date: Oct. 10, 2024

(54) REGENERATION OF DEGRADED SILICON PHOTOVOLTAIC MODULES: INDOOR AND OUTDOOR SOLUTIONS

(71) Applicant: ETAVOLT PTE LTD, Singapore (SG)

(72) Inventors: Zhi Peng LING, Singapore (SG); Chang-Kai Stanley WANG, Singapore (SG); Yong Heng SO, Singapore (SG)

(21) Appl. No.: 18/696,087

(22) PCT Filed: Oct. 19, 2022
(86) PCT No.: PCT/SG2022/050616

§ 371 Date: Mar. 27, 2024

(30) Foreign Application Priority Data
Aug. 27, 2021 (SG) 10202109421V

(51) Int. Cl. H01L 31/18

(52) U.S. Cl. CPC H01L 31/186; H01L 31/1804

(57) ABSTRACT

Silicon based photovoltaic (PV) systems deployed in the outdoor environment generally exhibit an annual performance degradation of ˜0.5% to 1% over its typical 20 to 25 years warranty period. In this invention disclosure, a solar module regeneration tool concept and its various embodiments is described, with its goal to provide PV performance maximization and recovery for both indoor (within the factory) and outdoor (at the installed PV system site) scenarios, in order to mitigate the degradation mechanisms and its impacts. The key benefits includes the following: (1) mitigating future performance drop for brand-new as-fabricated solar modules acting as performance degradation prevention, (2) outdoor performance recovery of degraded solar modules, (3) regeneration of solar modules as required without the need for disassembly, (4) extending solar modules' outdoor usage lifespan, and thus (5) directly reduce the cost of ownership (lower levelized cost of energy, LCOE), while promoting solar photovoltaic as the alternative renewable energy source over the lifespan of the solar modules. (6) the regeneration serves all types of Si based panels, including mono-facial, bifacial in any given size from single cell unit to 240 cell unit.

### CROSS REFERENCE TO RELATED APPLICATIONS

This patent application claims the benefit of Singapore Patent Application No. 10202109421V, filed 27 Aug. 2022. This application is an International Application based on the Singapore Patent Application which is incorporated by reference herein.

### BACKGROUND OF THE INVENTION

### A. Field of the Invention

The present invention relates to regeneration of degraded silicon photovoltaic modules, and in particular, to indoor and outdoor solutions of regeneration of degraded silicon photovoltaic modules. Silicon based photovoltaic (PV) systems deployed in the outdoor environment generally exhibit an annual performance degradation of ˜1% over its typical 20 to 25 years warranty period. In this invention disclosure, a solar module regeneration tool concept and its various embodiments is described, with its goal to provide PV performance maximization and recovery for both indoor (within the factory) and outdoor (at the installed PV system site) scenarios, in order to mitigate the degradation mechanisms and its impacts. The key benefits includes the following: (1) mitigating future performance drop for brand-new as-fabricated solar modules, (2) outdoor performance recovery of degraded solar modules, (3) regeneration of solar modules as required without the need for disassembly, (4) extending solar modules' outdoor usage lifespan, and thus (5) directly reduce the cost of ownership (lower levelized cost of energy, LCOE), while promoting solar photovoltaic as the alternative renewable energy source.

### B. Description of Prior Art

Silicon wafer based PV technology has been the dominant type of technology, accounting for ˜93% of total production in 2020, according to the International Technology Roadmap of Photovoltaics (ITRPV,2021). This report reveals that p-type silicon materials will stay mainstream, partly due to the maturity of the passivated emitter and rear contact (PERC) technology as well as the competitive pricing of p-type materials as compared to n-type materials. However, p-type silicon materials which are typically boron doped experience degradation when exposed to light, commonly known as light-induced degradation (LID). LID is believed to be caused by the formation of boron-oxygen (B—O) defects, although the exact mechanism is still a topic for contention. B—O related degradation can reduce the 1-sun standard test conditions (STC) efficiency of silicon solar cells by 3-4% in relative efficiency in aluminium back surface-field (AI-BSF) solar cells and 4-6% relative efficiency decrease in passivated emitter rear cell (PERC) solar cells, relative to the performance immediately after cell production. Although this degradation can be recovered naturally over time, this process varies greatly in time frame, causing an undesirable fluctuation in performance. This could cause cell manufacturers $390m based on an estimation made in 2017. The obvious practical and financial limitations caused by LID in Si solar cells has driven much research into various methods and parameters for regenerating B—O defects, thus recovering the solar cell performance. To-date, two major solar cell level approaches to achieve the regeneration process can be listed as illumination-based regeneration and electrical injection based regeneration. For the former, the utilized light sources are usually either halogen lamps with an illumination intensity up to 3 suns or lasers with single wavelengths ranging from 808 nm to 980 nm and intensity up to ˜100 suns for a duration of 10˜60 seconds. This coupled with the solar cells being exposed to an elevated temperature in the typical range of 200˜300° C. via methods such as a heated stage or a firing furnace was shown to mitigate the negative impact of LID, and in some instances also achieve higher cell efficiency than as fabricated. On the other hand, electrical injection regeneration approaches reported till date included current injection in the range of 3 A˜18 A at an elevated temperature in the range of 140˜260° C., for a duration of 20˜70 mins. Although both approaches do exhibit promising results in the performance recovery of silicon solar cells, the limitations can be listed as follows: (1) limited number of regeneration times: the solar cell level regeneration equipment is typically set up within the solar cell manufacturing production line, hence limiting the number of times the solar cells can be regenerated (typically only once) before these are assembled into PV modules and deployed in the outdoor environment, (2) once these PV modules are deployed, these are still prone to noticeable degradation (up to 12%). However, it is no longer possible to use the existing solar cell level regeneration tools to recover the performance of these PV modules easily, since the tools were originally designed to perform regeneration on a single solar cell basis, (3) even if the module level regeneration tool was available, it would entail the disassembly of the deployed PV modules and to-and-fro transportation back to the factory to be regenerated and re-assembly of the regenerated PV modules, which will interrupt the daily operation of the installed PV system. The invention disclosure in this document seeks to address these highlighted limitations.

### BRIEF SUMMARY OF THE INVENTION

These and other features, aspects and advantages of the present invention will become better understood with reference to the following drawings, description and claims.

A main object of the present invention focuses on solar module regeneration tool designs for both indoor (within the factory) and outdoor (at the deployed site) applications. The desired outcome is to prevent or minimize solar module performance degradation for as-fabricated new solar modules, as well as performance recovery for existing deployed PV systems in order to mitigate the degradation mechanisms and impacts. The key novelty and benefits of this tool design and its modified embodiments can be summarized as (1) flexibility, mobility and portability to conduct performance maximization or recovery for both indoor and outdoor cases, (2) ability for solar modules to be regenerated as required without the need for disassembly procedures, (3) Extend solar modules usage lifespans, (4) light induced degradation prevention and minimization for new modules and (5) directly reduce the cost of ownership (lower levelized cost of energy, LCOE), while promoting solar photovoltaic as the alternative renewable energy source. Six different embodiments are presented in this disclosure as possible designs for the solar module regeneration tool, depending on the application needs.

Yet another object of the present invention is to provide a solar panel laminator with regeneration device for laminate stack of solar cells comprising
a chamber including an upper chamber and a lower chamber having an upper face;
a heated platen with temperature adjustment control mounted directly beneath the upper chamber, being used to provide a target temperature to the laminate stack;
a cooling member connected to the chamber at the upper chamber for maintaining temperature of the regeneration device;
a conveyor apparatus for loading of the laminate stack of solar cells into the chamber of the laminator;
an illumination source for a regeneration process of the regeneration device being mounted at the upper face of the lower chamber; and
a vacuum pump being connected to the chamber to provide vacuum to the chamber, wherein the stack of solar cells is being regenerated simultaneously with a lamination process implemented to the laminate stack of solar cells via a plurality steps of vacuuming, heating and pressing.

Another object of the present invention provides advantages for the novel solar module regeneration tool in this disclosure as compared to a commercially available single solar cell regeneration tool are listed as follows:
(I) For indoor applications, although an indoor regeneration tool has demonstrated its feasibility to recover the solar cell performance and reduce the light induced degradation impacts, the existing setups reported in literature are often based on a single solar cell dimensions, and thus unable to be adapted to module level dimensions (for example: A typical 60-cell solar module has a dimension of 1.7 m×1 m, while a typical 72-cell solar module has a dimension of 2 m×1 m). At this point of writing, there is no/very limited literature reports of regeneration at the module level to the best of our knowledge. Even if there are regeneration tools of such dimensions, the PV installers will need time to disassemble the PV modules, followed by time to transport these PV modules to the regeneration tools, time to regenerate the PV modules, time to transport these PV modules back to the installation sites, and time to install them back into the system. The downtime involved in module level regeneration may already outweigh the potential gains from the PV system performance recovery. Thus, it is of immense benefit for a portable version of the solar module regeneration tool, which can deliver both indoor and outdoor PV performance recovery instead, which will ensure minimal downtime and maximum efficiency in the recovery process.
(II) Ability for solar modules to be regenerated as required without the need for disassembly. As mentioned earlier, although solar modules do recover from LID to varied extents upon long periods of sun exposure under normal working conditions, it is often unpredictable and thus impacts on the system reliability and performance expectations. The portable version of the solar module regeneration tool is envisaged to address that uncertainty by directly applying the regeneration process at the installed site, which can be performed as required, while avoiding the need to disassemble the modules. Using this approach, the degradation of the PV modules can be kept to a minimum, and thus achieve a consistently high PV system efficiency and electrical energy outputs.
(III) Regeneration on the module level with encapsulation and glass layers instead of on the solar cell level. The regeneration process can be positioned after or during the module lamination step, which is the last high temperature step in the module manufacturing process. The improvement from the regeneration process has a higher tendency to be locked in, since there are no further high temperature excitation which can destabilize the improvements. The lamination step typically has a temperature of >100° C.

Still another object of the present invention is to demonstrate the effectiveness of the regeneration process, single-cell silicon mini modules for all three dominant designs (P-Mono, P-Multi, and N-Mono) were fabricated as shown in FIG. 1, FIG. 2 and FIG. 3 respectively.

Still another object of the present invention is to provide a portable solar panel regeneration device comprises a portable solar panel regeneration gadget having a mobile cart with a computer/monitor and a PV regeneration tool, wherein a handheld regeneration tool is used 5 to perform regeneration for solar cells.

Yet still a further object of the present invention to provide a Regeneration of degraded silicon photovoltaic modules, wherein for the same regeneration light intensity (20 suns) and time (15 s), optimal effectiveness was observed at 70° C. for P-Mono, P-Multi and N-Mono silicon modules, which implies that the regeneration process can be executed at either within the solar lamination tool or at typical outdoor operating conditions without external heat stimulus. The various embodiments of the solar module regeneration tool in this invention disclosure aims to take advantage of the ability to perform regeneration under either typical indoor solar module manufacturing conditions or outdoor operating conditions, without the need to purchase any additional tools (thus reducing equipment footprint) or to disassemble any PV modules, thus maximizing PV system operational uptimes.

### BRIEF DESCRIPTION OF THE SEVERAL VIEWS OF THE DRAWING

A fuller understanding of the nature and objects of the present invention will become apparent upon consideration of the following detailed description, taken in connection with the accompanying drawings, wherein:

FIG. 1 shows a comparison of the P-Mono Silicon Solar Module efficiencies at different stages, wherein for DOE #2 (20 suns illumination, 70° C., 15 seconds time exposure), the best performance was obtained, with an efficiency increase of +0.79% absolute over the as-fabricated module, or equivalently +0.19W power increase/cell.

FIG. 2 shows a comparison of the P-Multi Silicon Solar Module efficiencies at different stages, wherein for DOE #2 (20 suns illumination, 70° C., 15 seconds time exposure), the best performance was obtained, with an efficiency recovery of +0.2% absolute from the degraded state, or equivalently +0.04W power increase/cell.

FIG. 3 shows a comparison of the N-Mono Silicon Solar Module efficiencies at different stages, wherein for regeneration DOE #2 (20 suns illumination, 70° C., 15 seconds time exposure), the regenerated mini module was able to avoid the light induced degradation experienced by the control module (reduction of 0.04W per solar cell).

FIG. 4 shows a comparison of the (a) levelized cost of energy (LCOE), considering solar modules alone, and varied years of usage from the typical 25 years up to 35 years, (b) LCOE savings increases as the solar modules useful lifespan increases with a suitable regeneration process.

FIG. 5A is a cross-sectional view of the hardware requirements for both (a) a conventional solar module laminator, and FIG. 5B is a cross-sectional view of (b) a novel solar module laminator with an integrated regeneration setup of the present invention, wherein for a novel design, the light source for the regeneration process is installed at the bottom to provide illumination onto the down-facing solar cells, while the heating component is now shifted to the top, and the light source can be either an array spanning the entire solar module, or single row/column/solar cell coverage combined with a scanning technique to regenerate the entire solar module, in accordance with the present invention.

FIG. 6 is a schematic of the novel two-in-one solar module lamination+regeneration tool for the preferred embodiment of the present invention, wherein for this design, the regeneration process can take place simultaneously while the lamination process is ongoing, with no additional equipment space required.

FIG. 7 is a schematic of the portable solar module regeneration tool for the first modified embodiment (#1) of the present invention, wherein the dimensions of the tool are chosen to match the typical module dimensions, and to perform regeneration for 1 row/column of solar cells within the module at each instance.

FIG. 8 is a schematic of the portable solar module regeneration tool for the first modified embodiment (#1) of the present invention, wherein the solar modules are included in this schematic, and the movement direction of the portable solar module regeneration tool is indicated, and in this manner, an array of solar modules can be regenerated for every usage in accordance with the present invention.

FIG. 9 is a schematic of the portable solar module regeneration tool for the modified embodiment #2 of the present invention, wherein the present setup consists of a mobile cart with an industrial grade waterproof touchscreen computer/monitor, and a full module PV regeneration design in accordance with the present invention.

FIG. 10 is a schematic of the portable solar module regeneration tool for the modified embodiment #3 of the present invention, wherein the present setup consists of a mobile cart with an industrial grade waterproof touchscreen computer/monitor, and a handheld regeneration tool to perform regeneration for selected solar cells which are determined to be exhibiting lower performance in accordance with the present invention.

FIG. 11 is a schematic of the portable solar module regeneration tool for the modified embodiment #4 of the present invention, wherein the setup consists of a handheld regeneration tool to perform regeneration for selected solar cells which are determined to be exhibiting lower performance in accordance with the present invention.

### DETAILED DESCRIPTION OF THE INVENTION

The following detailed description is of the best currently contemplated modes of carrying out exemplary embodiments of the invention. The description is not to be taken in a limiting sense, but is made merely for the purpose of illustrating the general principles of the invention, since the scope of the invention is best defined by the appended claims.

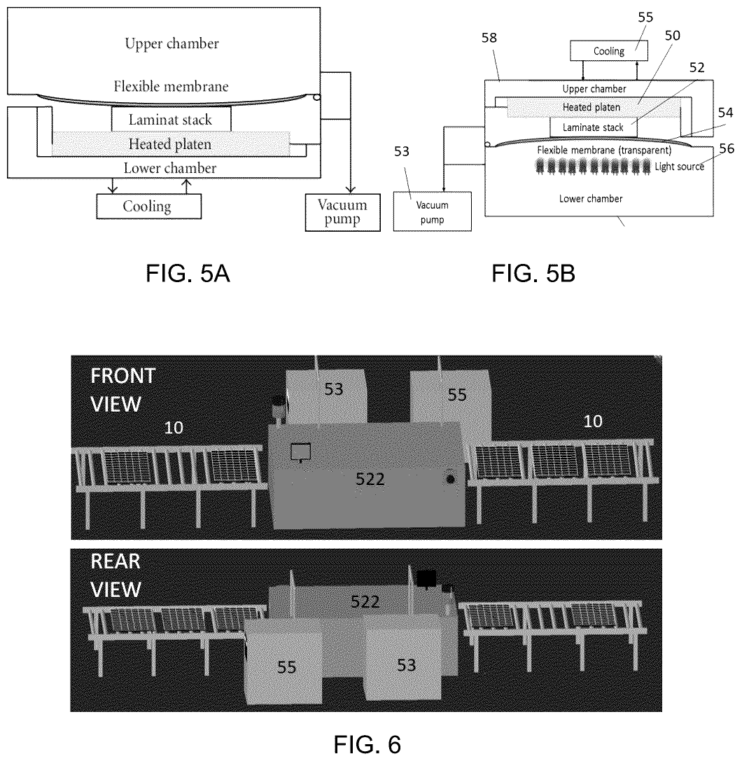

Referring to FIGS. 5B and 6, broadly, which show the regeneration process in accordance with the present invention. The shortcomings of the prior art are overcome and additional advantages are provided by the present invention. The preferred embodiment is shown in FIG. 5B and FIG. 6, which integrates the regeneration process within the solar module lamination process. For a conventional solar module lamination process seen in FIG. 5A, the incoming laminate stack comprising of Glass, EVA, Solar cells, EVA, and Backsheet are subjected to a concurrent process of vacuuming, heating, and pressing in order to adhere the EVA layer to the neighbouring layers. The front-side of the solar cells will be down-facing, while the backsheet will be top-facing. The preferred embodiment considers an alternative setup as shown in FIG. 5B, comprising a heated platen (50), where the heating platen (50) is now placed on the top of a laminate stack (52) and adopts a transparent flexible membrane material (54) on the bottom of the laminate stack (52), which will maximize the transmission of the illumination from the regeneration light source (56) upon the down-facing solar cells as part of the regeneration process. The illumination or light source (56) can be either configured as an array spanning the entire solar module, or single row/column/solar cell coverage combined with a scanning technique to regenerate the entire solar module. The illumination or light source (56) will have an adjustable intensity from less than one sun intensity and up to 100 suns intensity. Depending on the illumination intensity, the regeneration time per solar cell can range from as fast as 5 seconds to several minutes. From past experimental results, the surface temperature of the PV modules will also contribute to the efficiency of the regeneration process, and can range from room temperature 25° C. (300K) up to (but not limited to) 300° C. (575K). The illumination or light source (56) can include but not limited to the following: (a) laser, (b) light emitting diodes (LEDs), (c) halogen incandescent lamps, (d) fluorescent light, (e) metal halide light sources, (f) xenon strobe lamps (g) IR lamps and (h) light and sunlight concentrators. The regeneration chamber (522) has an upper chamber (58) which is linked to a cooling member (55), and a vacuum pump (53) connected thereto.

FIG. 6 shows a schematic of the preferred embodiment, depicting a novel two-in-one solar module lamination and regeneration tool. The tool shown comprises of a conveyor system (10) to load a laminate stack (52) of Glass/EVA/solar cells/EVA/backsheet into the novel laminator and regeneration chamber (522). The tool then executes a concurrent task of vacuuming by the vacuuming pump (53), platen heating to a target temperature, pressing by the transparent flexible membrane (54), and regeneration light source (56) exposure. The temperature within the tool is maintained by the cooling member or the chiller (55) for the entire process, which regulates the temperatures on the heated platen (50) and the regeneration light sources (56). Once completed, the laminated+regenerated solar modules are unloaded onto an outgoing conveyor system (10) to the next station.

For this preferred embodiment, the regeneration process can take place simultaneously while the lamination process is ongoing, with no additional equipment footprint required. Based on experimental results and typical lamination process time, no additional overheads on process time is expected, while the outgoing solar modules will now be protected against outdoor performance degradation issue.

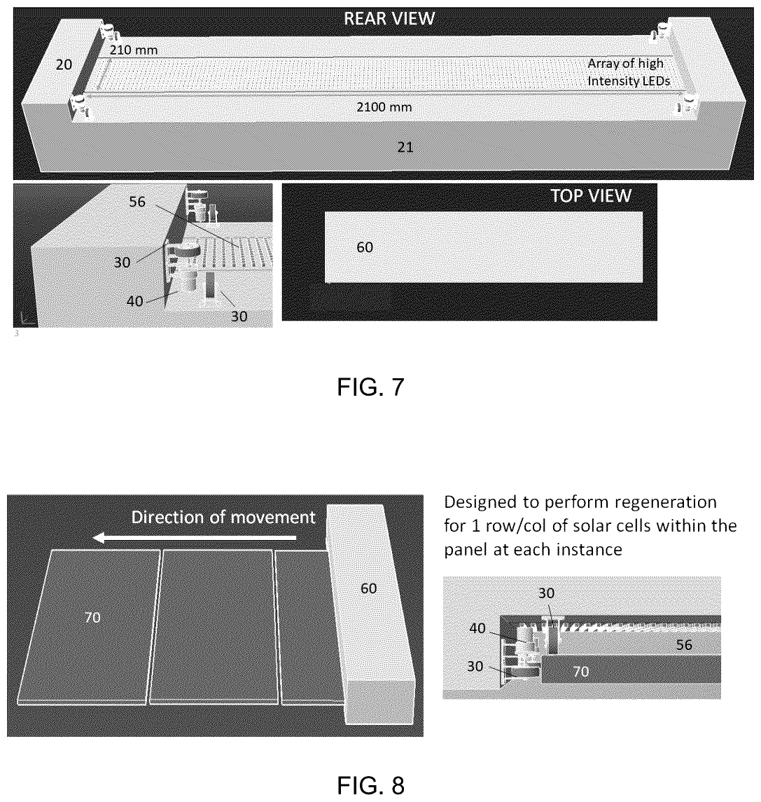

The first modified embodiment (#1) is shown in FIG. 7, wherein the tool (20) as shown comprises a compartment (21) containing the electronics components responsible for the movement as well as the light regeneration process. The electronics components will include but not limited to the followings: (a) batteries, (b) circuit boards and microcontrollers, and (c) wireless transmitter and receiver to feedback or control the regeneration status. The incoming or outgoing feedback signals that are received wirelessly or manually are interpreted by the microcontroller, and translated to both movement and illumination either concurrently or independently. The dimensions of the tool are chosen to match the typical module dimensions, and to perform regeneration for 1 row/column of solar cells within the module at each instance. The movement of the tool is facilitated by wheels (30) at the four edges of the tool, which are powered by a DC motor (40), which in turn is controlled by the microcontrollers in the electronic compartment (21). For the light regeneration, this is established by an array of illumination source (56), with an adjustable intensity from less than one sun intensity and up to 100 suns intensity. Depending on the illumination intensity, the regeneration time per solar cell can range from as fast as 5 seconds to several minutes. Similar to the indoor regeneration tool, the surface temperature of the PV modules will also contribute to the efficiency of the regeneration process, and can range from room temperature 25° C. (300K) up to (but not limited to) 300° C. (575K). The illumination sources (56) can include but not limited to the following: (a) laser, (b) light emitting diodes (LEDs), (c) halogen incandescent lamps, (d) fluorescent light, (e) metal halide light sources, (f) xenon strobe lamps (g) IR lamps and (h) light and sunlight concentrators.

The distance between the pairs of wheels (illustrated in FIG. 7) can be adjusted to accommodate different lengths of the PV modules.

A typical silicon PV system will have multiple PV modules placed in a sequential array in close proximity to each other, as indicated by reference number (70) of FIG. 8. FIG. 8 shows the regeneration tool in normal operation. The regeneration tool will be placed with the illumination source facing downwards, and the rear side facing upwards, as shown by reference number (60). The tool will move across the array of PV modules with the intended illumination intensity, regeneration time, and targeted surface temperature to maximize the regeneration benefits. In this embodiment, the regeneration tool only requires enough illumination sources to perform regeneration for 1 row/column of solar cells within the module at each instance, thus reducing the amount of illumination sources and the corresponding hardware requirements. Once all regeneration is done, the tool of the present invention will be brought to the charging station to recharge the in-built batteries for the next usage.

The second modified embodiment (#2) is to include a built-in cleaning and characterization unit within the regeneration tool sketched in FIG. 7. Given that solar modules are deployed in outdoor environments, these have a tendency to accumulate dirt and debris over time, which will create a shading issue as well as reduce the efficacy of the regeneration process on affected areas. In addition, the potential customers could also be interested to have a technical performance comparison before and after the regeneration process on individual solar modules. One plausible sequence is in the order of cleaning, pre-regeneration inspection, actual regeneration, and finally post-regeneration inspection.

Particularly for modified embodiment #2, the tool will first have an integrated cleaning mechanism to remove most of the dirt and debris on the solar module surface. The cleaning setup may include but not limited to the following: (a) water-based cleaning with water and rotating brushes, (b) water-based cleaning with high pressure water alone, avoiding the need for brushes and (c) dry cleaning with dust repellent rotating brushes. The choice of the preferred cleaning setup will depend on the solar module deployment location, and the accessibility to water. The tool will also be equipped with characterization capability right beside the array of high intensity illumination source. The characterization setup may include but not limited to the following: electroluminescence, photoluminescence or infrared thermography imaging. The additional electronic components may include but not limited to the followings: (a) sensors (charge coupled devices-CCD, or complementary metal oxide semiconductors-CMOS) adopting materials such as silicon, InGaAs or other variants; (b) IR cameras with the desired detector resolution, image display, spectral range, thermal sensitivity, accuracy of reading and focus mode; and (c) data collection and transmitting system for transmitting measured data to another computer for data analysis. The scanning can either take place via a line scan approach or the area scan approach, depending on the resolution or speed requirements among other technical requirements.

In normal operation of modified embodiment #2, while the tool is moving across the array of PV modules, it is also concurrently performing cleaning and characterization data collection via a scanning approach. The raw data is sent manually or wirelessly to another computer for data analysis and performance monitoring. When the characterization setup is placed both to the left and right of the illumination source (56), the portable regeneration tool can keep track of the characterization results before the regeneration and after the regeneration process.

The key advantages of adopting modified embodiment #2 includes the following: (a) real-time PV module cleaning, (b) real-time PV module performance characterization and monitoring, (c) real-time feedback of regeneration effectiveness, (d) higher resolution quality of the characterization data since the measurement is carried out in close proximity, as compared to existing approaches such as drones, (e) time and cost efficient since both measurement and regeneration process are done at the same time, as compared to the conventional approach of measurement, data analysis, and selective replacement of problematic PV modules.

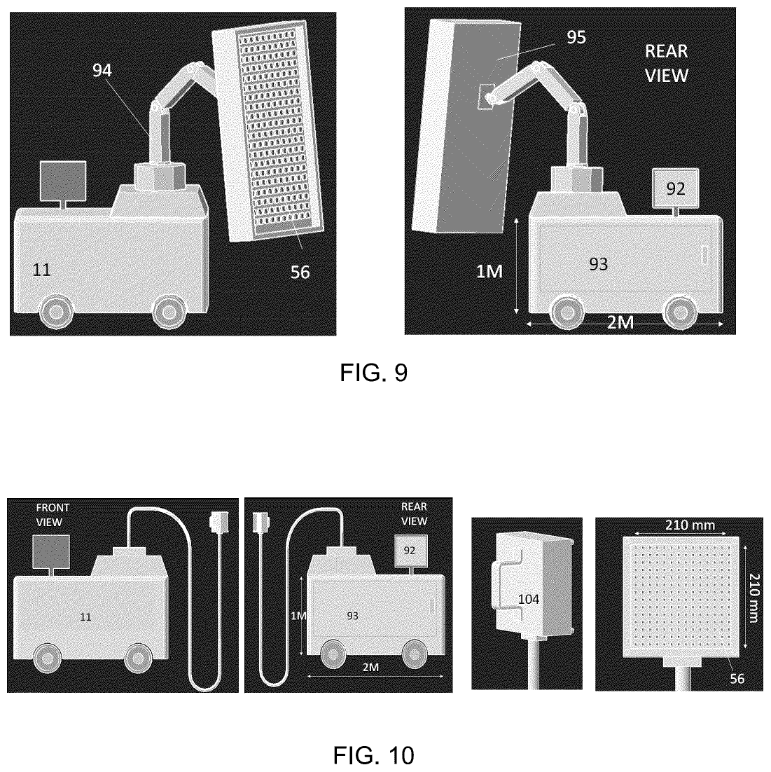

The third modified embodiment (#3) is shown in FIG. 9. The tool (11) shown in comprises of a mobile cart, equipped with an industrial grade waterproof touchscreen computer/monitor (92), a compartment (93) containing the electronics components responsible for the robotic arm (94) movement as well as the light regeneration process. The electronics components will include but not limited to the followings: (a) batteries, (b) circuit boards and microcontrollers, and (c) wireless transmitter and receiver to feedback or control the regeneration status. The incoming or outgoing feedback signals that are received wirelessly or manually are interpreted by the microcontroller, and translated to both movement and illumination either concurrently or independently. The movement of the tool is facilitated by wheels, which are powered by the DC motors, which in turn is controlled by the microcontrollers in the electronic compartment (93), established either via manual inputs or remotely controlled of the computer/monitor (92).

The key difference from the modified embodiment #1 lies in the ability for modified embodiment #3 to perform a full module regeneration process at one instance. Thus, the dimensions of the regeneration box (95) are chosen to match a typical solar PV module dimensions, which can include but not limited to the followings: (a) 60-cell module: 1.7 m×1 m, (b) 72-cell module: 2 m×1 m or (c) other number of cells modules. The regeneration box (95) is established by an array of illumination source (56), with an adjustable intensity from less than one sun intensity and up to (but not limited) 100 suns intensity. Depending on the illumination intensity, the regeneration time per solar cell can range from as fast as 5 seconds to several minutes. Similar to the indoor regeneration tool, the surface temperature of the PV modules will also contribute to the efficiency of the regeneration process, and can range from room temperature 25° C. (300K) up to (but not limited to) 300° C. (575K). The illumination sources (56) can include but not limited to the followings: (a) laser, (b) light emitting diodes (LEDs), (c) halogen incandescent lamps, (d) fluorescent light, (e) metal halide light sources, and (f) xenon strobe lamps.

In the normal operation, when a particular outdoor PV module is identified to undergo a regeneration process, the user either manually or remotely sends the commands through the computer/monitor (92), which will control the robotic arm (94) responsible for moving the regeneration box (95) towards the PV module, and encloses the PV module in its entirety, before activating the illumination source (56) for light regeneration. Once a particular PV module has completed the regeneration process, the robotic arm (94) will retract the regeneration box (95), followed by tool (11) moving to the next location, and the whole regeneration process is repeated. Once all regeneration is done, tool (11) will be brought to the charging station to recharge the in-built batteries for the next usage.

The key advantages of this approach is that the dimensions of the regeneration box (95) can be designed to be bigger than the dimensions of the PV modules, hence permitting a one-size fits all concept. The compartment (93) is also expected to be more spacious than the preferred embodiment, facilitating future upgrades if desired. There is also no need to identify which particular solar cell is performing poorer in a single module, as all solar cells within the same module are regenerated at one instance.

The fourth modified embodiment (#4) is shown in FIG. 10. The tool (11) shown in comprises of a mobile cart, equipped with an industrial grade waterproof touchscreen computer/monitor (92), a compartment (93) containing the electronics components responsible for the tool movement as well as the light regeneration process. The electronics components will include but not limited to the followings: (a) batteries, (b) circuit boards and microcontrollers, and (c) wireless transmitter and receiver to feedback or control the regeneration status. The incoming or outgoing feedback signals that are received wirelessly or manually are interpreted by the microcontroller, and translated to both movement and illumination either concurrently or independently. The movement of the tool is facilitated by wheels, which are powered by the DC motors, which in turn is controlled by the microcontrollers in the electronic compartment (93), established either via manual inputs or remotely controlled by the computer/monitor (92).

The key difference from the preferred embodiment lies in the ability for modified embodiment #4 to perform regeneration process for any individual solar cell within the PV module. Prior to using the tool, an independent on-site inspection of the PV module which can include but not limited to the following techniques such as electroluminescence, photoluminescence or infrared thermography imaging is expected to be performed (not sketched here), which will return a visual representation of every single cell performance within the module. From the results, the user can determine which solar cells are to be subjected to the regeneration process via the handheld regeneration box (104). The handheld regeneration box (104) is equipped with a handle at the rear for easy handling, and an array of illumination source (56) at the front for the light regeneration process. Given that the silicon wafers dimensions can vary between different wafer manufacturers, the dimensions of the handheld regeneration box (104) (or the area of illumination within the box) are chosen to match the typical silicon solar cell dimensions, which can include but not limited to the followings: (a) 125 mm×125 mm, (b) 156 mm×156 mm, (c) 156.75 mm×156.75 mm, (d) 161.7 mm×161.7 mm, (e) 166 mm×166 mm, (f) 210 mm×210 mm or larger dimensions. In particular, the sketched handheld regeneration box adopts the current known largest dimensions of 210 mm×210 mm, so that it can be backward compatible as well. The handheld regeneration box (104) is established by an array of illumination source, with an adjustable intensity from less than one sun intensity and up to (but not limited to) 100 suns intensity. Depending on the illumination intensity, the regeneration time per solar cell can range from as fast as 5 seconds to several minutes. Similar to the indoor regeneration tool, the surface temperature of the PV modules will also contribute to the efficiency of the regeneration process, and can range from room temperature 25° C. (300K) up to (but not limited to) 300° C. (575K). The illumination sources can include but not limited to the followings: (a) laser, (b) light emitting diodes (LEDs), (c) halogen incandescent lamps, (d) fluorescent light, (e) metal halide light sources, and (f) xenon strobe lamps.

In the normal operation, once a particular solar cell within the PV module has been identified to undergo the regeneration process, the user brings the handheld regeneration box (104) as close as possible to the target solar cell, switches on the illumination sources to execute the regeneration process, switches it off upon completion, and moving on to the next solar cell requiring regeneration process. When all the identified solar cells within the PV module has completed the regeneration process, the tool (11) can be shifted to the next location, and the whole inspection/regeneration process is repeated. Once all regeneration is done, tool (11) will be brought to the charging station to recharge the in-built batteries for the next usage.

The key advantage of this approach is that the regeneration process can be performed on a handheld tool, which requires significantly lower amount of illumination sources and associated hardware and thus achieve lower tool costs. There can be selectivity in the choice of solar cells for the regeneration process especially on the poorer performing solar cells, in order to recover their performance to match the non-regenerated solar cells. The compartment (93) is also expected to be more spacious than the modified embodiment #1, facilitating future upgrades if desired.

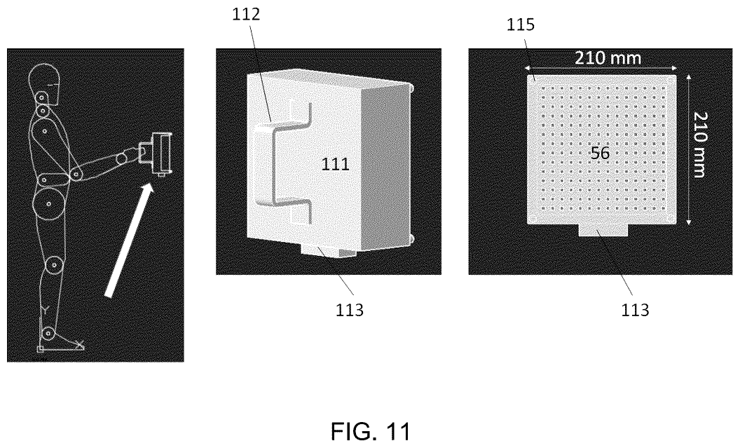

The fifth modified embodiment (#5) is shown in FIG. 11. The handheld regeneration box shown in (111) comprises of a handle (112) and a compartment (113) containing the electronics components responsible for the switches (on/off), charging ports as well as the light regeneration process. The electronics components will include but not limited to the followings: (a) batteries, (b) circuit boards and microcontrollers, and (c) wireless transmitter and receiver to feedback or control the regeneration status. There are protruded stoppers (115) at the four corners of the handheld regeneration tool to act both as a guide to the targeted solar cell as well as to minimize direct contact of the tool to the glass side of the PV module. The handheld regeneration box (111) is equipped with a handle at the rear for easy handling, and an array of illumination source (56) at the front for the light regeneration process. Given that the silicon wafers dimensions can vary between different wafer manufacturers, the dimensions of the handheld regeneration box (111) (or the area of illumination within the box) are chosen to match the typical silicon solar cell dimensions, which can include but not limited to the followings: (a) 125 mm×125 mm, (b) 156 mm×156 mm, (c) 156.75 mm×156.75 mm, (d) 161.7 mm×161.7 mm, (e) 166 mm×166 mm, (f) 210 mm×210 mm or larger dimensions. In particular, the sketched handheld regeneration box adopts the current known largest dimensions of 210 mm×210 mm, so that it can be backward compatible as well. The handheld regeneration box (111) is established by an array of illumination source, with an adjustable intensity from less than one sun intensity and up to (but not limited to) 100 suns intensity. Depending on the illumination intensity, the regeneration time per solar cell can range from as fast as 5 seconds to several minutes. Similar to the indoor regeneration tool, the surface temperature of the PV modules will also contribute to the efficiency of the regeneration process, and can range from room temperature 25° C. (300K) up to (but not limited to) 300° C. (575K). The illumination sources can include but not limited to the followings: (a) laser, (b) light emitting diodes (LEDs), (c) halogen incandescent lamps, (d) fluorescent light, (e) metal halide light sources, and (f) xenon strobe lamps.

In the normal operation, once a particular solar cell within the PV module has been identified to undergo the regeneration process, the user brings the handheld regeneration box (111) as close as possible to the target solar cell, switches on the illumination sources to execute the regeneration process, switches it off upon completion, and moving on to the next solar cell requiring regeneration process. When all the identified solar cells within the PV module has completed the regeneration process, the regeneration box (111) can be shifted to the next location, and the whole inspection/regeneration process is repeated. Once all regeneration is done, the regeneration box (111) will be brought to the charging station to recharge the in-built batteries for the next usage. In a variation of the normal operation, the regeneration process may also be conducted by a robot or on a drone. Upon location of the PV cells/module to be regenerated, the mobile unit can be dispatched to the location for regeneration. Upon completion of regeneration, the unit can be returned back to its charging station.

The key difference from the preferred embodiment lies in the ability for modified embodiment #5 to perform regeneration process for any individual solar cell within the PV module. Prior to using the regeneration box (111), an independent outdoor inspection of the PV module is conducted which can include but not limited to the following techniques such as electroluminescence, photoluminescence or infrared thermography imaging (not sketched here), which will return a visual representation of every single cell performance within the module. From the results, the user can determine which solar cells are to be subjected to the regeneration process via the handheld regeneration box (111).

The key advantages of this approach is that the regeneration process can be performed on a handheld tool, which requires significantly lower amount of illumination sources and associated hardware and thus achieve lower tool costs. There can be selectivity in the choice of solar cells for the regeneration process especially on the poorer performing solar cells, in order to recover their performance to match the non-regenerated solar cells.

The novel solar module level regeneration tool has some clear distinct advantages over the conventional indoor solar cell level regeneration box (111). The key novelty and benefits of this tool can be summarized as (i) indoor solar module performance degradation prevention for new modules in the factory and outdoor performance recovery in the field, (ii) ability for solar modules to be regenerated as required without the need for disassembly, (iii) potential to extend solar modules usage lifespan, and thus (iv) directly reduce the cost of ownership (lower levelized cost of energy, LCOE), while promoting solar photovoltaic as the alternative renewable energy source. Thus, by integrating the disclosed solar module regeneration tools and its variants as a value adding service to existing solar module manufacturers, EPC and O&M providers as well as end-consumers, it will encourage lower cost of ownership, increase electricity collection outputs and thus encourage more adopters of PV systems and more sales.

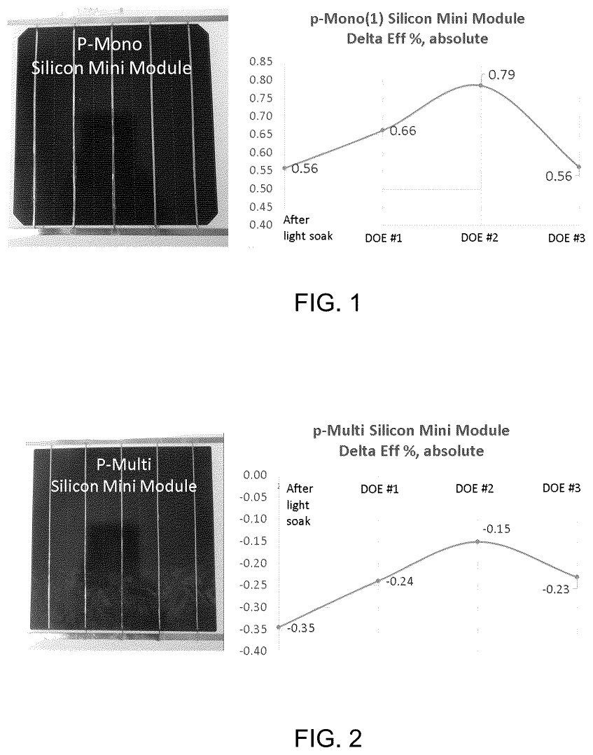

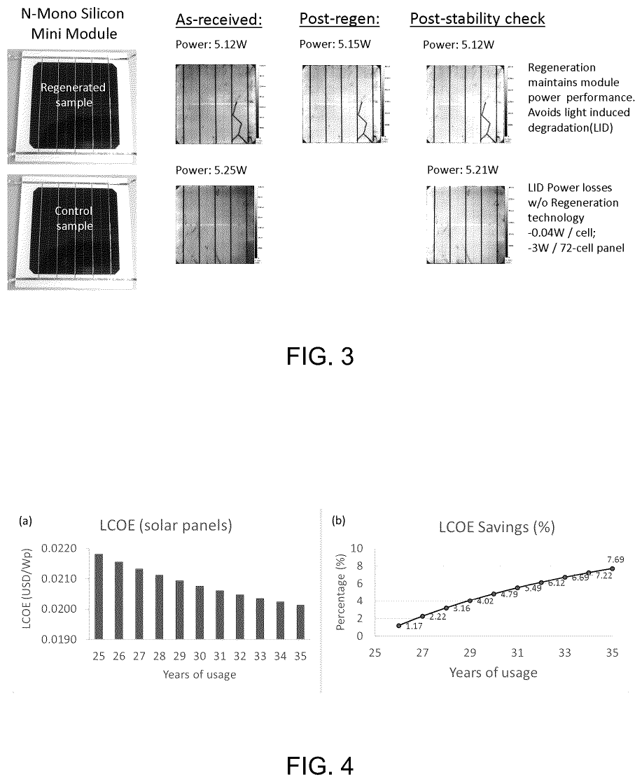

The invention focuses on several embodiments of the novel solar module regeneration tool for both indoor performance degradation prevention of new modules in the factory and outdoor PV system performance recovery. Although there are clear advantages as compared to an indoor solar cell level regeneration tool, some potential challenges are listed as follows:
(I) Achieving high illumination intensity and uniformity: As highlighted earlier in the background studies, the indoor solar cell regeneration tool are typically designed to process one solar cell at a time and for the case of laser based regeneration, utilizes a high power laser, coupled with several optical components, placed at a precise distance from each other in order to achieve the targeted intensity and area uniformity. Thus, for a portable version of the regeneration tool which needs to cater to various dimensions such as single solar cell, a row/column of cells, or an entire module of solar cells, there is increased complexity in selecting the appropriate hardware to provide the same high illumination intensity and area uniformity.
(II) Controlling surface temperature of the regenerated solar cells: For both the indoor regeneration tools utilizing either illumination based or electrical injection-based regeneration, the optimal temperature for regeneration was in the typical range of 140˜300° C. On the other hand, it is to be noted that for a silicon PV module, the silicon solar cells are encapsulated by an ethylene-vinyl acetate (EVA) copolymer in order to prevent moisture and dirt from penetrating the PV modules. However, this EVA is reported to have a typical flash point temperature of ˜260° C., and an auto-ignition temp of <350° C. This means that the optimal regeneration conditions used for individual solar cells could potentially lead to fire hazards on module levels.
(I) Achieving high illumination intensity and uniformity: Besides the usage of laser-based systems, other alternatives as mentioned in the disclosure can be considered such as (a) light emitting diodes (LEDs), (b) halogen incandescent lamps, (c) fluorescent light, (d) metal halide light sources, and (e) xenon strobe lamps. It is to be further evaluated which of these candidates exhibit more potential to be integrated into the final design. The goal is to achieve the targeted illumination intensity and area uniformity for the regeneration process.
(II) Controlling surface temperature of the regenerated solar cells: There is a direct correlation between the choice of the illumination intensity and the exposure time on the surface temperature of the solar cell, considering the additional EVA and glass layer on the top as well. There is a need for further evaluation and optimization of the regeneration conditions at the module level, which may be different from regeneration at the solar cell level. Preliminary results conducted on silicon cell mini modules shown in FIG. 1 to FIG. 3 appears to indicate that no additional temperature stimulus is required if considering outdoor regeneration.

One of the competing way to perform on-site regeneration of solar modules is to disconnect the individual modules from the array, followed by subjecting them to an electrical injection regeneration process. However, this approach will introduce disruption to the normal PV systems operation, and requiring additional electrically certified manpower and costs to perform disconnection and reconnection of the PV modules. Our solar module regeneration tool designs in this disclosure can be applied both indoors and outdoors, stationary and portable without the need to disconnect the modules, thus minimizing downtime and PV outputs disruption, while recovering the PV system performance to its peak in the shortest time possible.

The foregoing is illustrative of the present invention and is not to be construed as limiting thereof. Although exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. This invention is defined by the following claims, with equivalents of the claims to be included therein.

1. A solar panel laminator with regeneration device for a laminate stack of solar cells having a chamber including an upper chamber and a lower chamber with an upper face comprising
a heated platen with temperature adjustment control mounted directly beneath the upper chamber, being used to provide a target temperature to the laminate stack;
a cooling member connected to the chamber at the upper chamber for maintaining temperature of the regeneration device, regulating the temperature of the heated platen;
a conveyor apparatus for loading of the laminate stack of solar cells into the chamber of the laminator;
an illumination source for a regeneration process of the regeneration device being mounted at the upper face of the lower chamber, wherein the illumination source is configured as an array spanning the solar panel laminate, allowing the array spanning of the entire solar module, or single row solar cell coverage combined with a scanning technique to regenerate the entire solar module, which allows the regeneration period, the illumination intensity and target temperature per individual solar cell to be adjusted and optimized, independent of the optimal settings for the lamination process; and
a vacuum pump being connected to the chamber to provide vacuum to the chamber, wherein the stack of solar cells is being regenerated simultaneously with a lamination process implemented to the laminate stack of solar cells via a plurality steps of vacuuming, heating and pressing.

2. The solar panel laminator with regeneration device as set forth in claim 1, wherein the regeneration process is taking place simultaneously while the lamination process is ongoing.

3. The solar panel laminator with regeneration device as set forth in claim 2, wherein no additional equipment footprint except the solar panel laminator is required when the regeneration process is taking place.

4. The solar panel laminator with regeneration device as set forth in claim 1, wherein the solar cell for regeneration has a front side which faces downward to the illumination source and has a backsheet which faces upward away from the illumination source, and wherein the illumination source is solely tailored for the optimal regeneration process for the individual solar cells within a solar panel.

5. The solar panel laminator with regeneration device as set forth in claim 1, wherein the laminator is effective on regeneration process for P-Mono, P-Multi, N-Cast Mono, N-Multi, N-Mono silicon solar modules.

6. The solar panel laminator with regeneration device as set forth in claim 1, wherein the illumination source is configured in single row solar cell coverage combined with a scanning device to regenerate the stack of solar cells, and wherein the scanning device allows adjusting and optimizing of settings of the regeneration and lamination process with respect to a regeneration period, illumination intensity and a target temperature per individual solar cell or row/column of solar cells.

7. The solar panel laminator with regeneration device as set forth in claim 1, wherein the illumination source has adjustable intensity of less than one sun intensity up to 100 suns intensity.

8. The solar panel laminator with regeneration device as set forth in claim 1, wherein the regeneration device has a regeneration period of at least 5 seconds and up to 30 minutes per solar cell.

9. The solar panel laminator with regeneration device as set forth in claim 1, wherein the cooling member is functioned to maintain a temperature within the stack of solar cells, and regulates the temperature of the illumination source.

10. The solar panel laminator with regeneration device as set forth in claim 1, wherein a completed laminated and regenerated solar modules are unloaded onto a conveyor system.

11. The solar panel with regeneration device as set forth in claim 1, wherein the lamination source includes laser, light emitting diodes, halogen incandescent lamps, fluorescent light, metal halide light xenon strobe lamps, infrared lamps and light and sunlight concentrators, which is solely functioned to perform light based regeneration of the individual solar cells within the solar panels in the most optimal intensity and regeneration period.

12. The solar panel laminator as set forth in claim 1, wherein a mobile cart is used to accommodate the regeneration device automatically by scanning along the string/array of the solar panels on site.

13. The solar panel laminator as set forth in claim 13, wherein the mobile cart is equipped with a computer/monitor and a photovoltaic module regeneration tool.
